(19) United States
(12) Patent Application Publication
(10) Pub. No.: US 2025/0063798 A1
(43) Pub. Date: Feb. 20, 2025

(54) DRIVER STAGE CURRENT DENSITY ENHANCEMENT

(71) Applicant: Intel Corporation, Santa Clara, CA (US)

(72) Inventors: Yuri Rozenfeld, Haifa (IL); Yishai Eilat, Haifa (IL); Elham Mohammadi, Portland, OR (US); Naor Roi Shay, Rehovot (IL); Anna Nazimov, Haifa (IL)

(21) Appl. No.: 18/233,966

(22) Filed: Aug. 15, 2023

(51) Int. Cl. H01L 29/417; H01L 27/02; H01L 27/088; H01L 29/78

(52) U.S. Cl. CPC H01L 29/41758; H01L 27/0207; H01L 27/0886; H01L 29/7835

(57) ABSTRACT

A transistor device can include a drain contact operably connected to a drain finger and a source contact operably connected to a source finger. The transistor device can further include diffusion area connected to the drain finger and the source finger to provide current to the drain finger and the source finger. The drain finger can have a length extending along an axis and different drain finger widths along the drain finger length such that current density is equal at each point along the drain finger length. The source finger can have a length extending along the axis and source finger widths along the source finger length such that current density is equal at each point along the source finger length.

### TECHNICAL FIELD

Aspects pertain to electronic devices. In particular, aspects relate to transistor architecture for transistors used in electronic devices.

### BACKGROUND

Power amplifiers and driver stages are used in a variety of applications. The choice and design of electrical components can affect key performance indicators of power amplifiers and associated circuits or driver stages of communication devices or other devices. For example, device packages for a radio frequency (RF) power amplifier can include a transistor die (e.g., metal-oxide semiconductor field-effect transistor (MOSFET)). Reducing or minimizing parasitic capacitance and coupling within the MOSFET may improve key performance indicators for the driver stage and for devices including the respective driver stage.

### BRIEF DESCRIPTION OF THE DRAWINGS

FIG. 1 illustrates an exemplary front end module (FEM) circuitry that can include transistor circuitry in accordance with some aspects.

FIG. 2 illustrates a transistor device in accordance with some aspects.

FIG. 3 illustrates example proportions and layout of transistor devices in accordance with some aspects.

FIG. 4 is a function block diagram of a wireless communication device, in accordance with some aspects.

### DETAILED DESCRIPTION

The following description and the drawings sufficiently illustrate specific aspects to enable those skilled in the art to practice them. Other aspects may incorporate structural, logical, electrical, process, and other changes. Portions and features of some aspects may be included in, or substituted for, those of other aspects. Aspects set forth in the claims encompass all available equivalents of those claims.

Radio communication apparatuses may include power amplifier (PA) devices. Power amplifier resistance and output capacitance are two of the main parameters defining key performance indicators (KPIs) of the PA and circuits including the PA. Some high frequency PA circuit devices can include Metal Oxide Semiconductor Field-Effect-Transistors (MOSFETs) and MOSFET layout decisions can be made to adjust parameters that affect KPIs. For example, to reduce parasitic resistance, a metal overlay can be provided over the contacts of the MOSFET and the number of electrical connections (e.g., vias or through-vias) can be increased or maximized. However, this can result in additional parasitic capacitance. On the other hand, steps to minimize coupling to reduce parasitic capacitance can increase the layout area of the MOSFET, causing packaging concerns and size concerns.

Systems, apparatuses and methods according to some aspects of the disclosure address these and other concerns by providing a layout solution that maintains adequate current density throughout the MOSFET without increasing size or layout area of the MOSFET and without additional parasitic “ON” resistance or parasitic capacitance. Proposed solutions enable efficient current distribution through the MOSFET and increase driver stage and output stage efficiency.

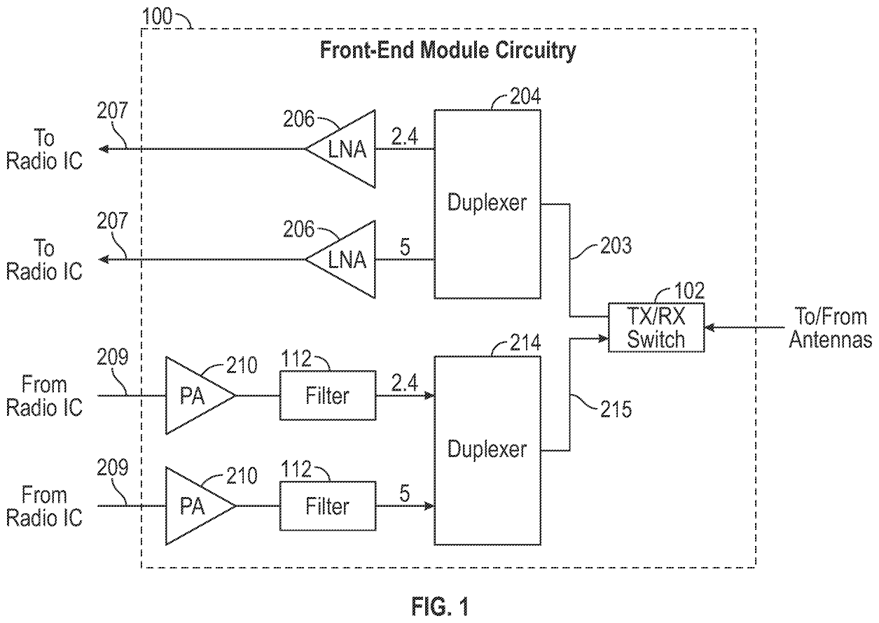

FIG. 1 illustrates front end module (FEM) circuitry 100 that can include MOSFETs or other transistor circuitry in accordance with some aspects. In some aspects, the FEM circuitry 100 may include a TX/RX switch 102 to switch between transmit mode and receive mode operation. The FEM circuitry 100 may include a receive signal path and a transmit signal path. The receive signal path of the FEM circuitry 100 may include a low-noise amplifier (LNA) 206 to amplify received RF signals 203 and provide the amplified received RF signals 207 as an output. The transmit signal path of the circuitry 100 may include a power amplifier (PA) to amplify input RF signals 209, and one or more filters 112, such as band-pass filters (BPFs), low-pass filters (LPFs) or other types of filters, to generate RF signals 215 for subsequent transmission (e.g., by one or more of antennas (not shown in FIG. 1).

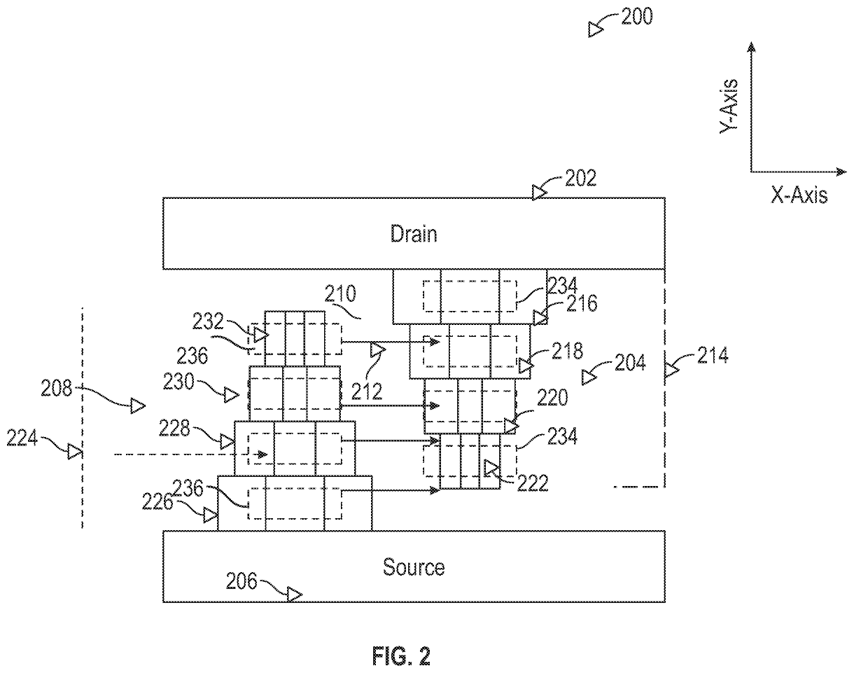

One or more of the PAs described above can include transistor circuitry and overall parasitics should be kept as low as possible while maintaining current density throughout the transistor. Transistors according to example embodiments can maintain current density using routing and configuration as shown in FIG. 2. The routing and tapering configuration shown in FIG. 2 can maintain a constant current density along FET fingers 204, 208 (FIG. 2) without increasing the coupling between FET fingers 204, 208. This routing will have a tapered shape. Increased metal width on one finger side and decreased on the other.

FIG. 2 illustrates a transistor device 200 in accordance with some aspects. The transistor device 200 can include a drain contact 202 electrically connected to a drain finger 204. The transistor device 200 can include a source contact 206 electrically connected to a source finger 208. The transistor device 200 can include a diffusion area 210 between the drain finger 204 and the source finger 208 to provide current 212 between the drain finger 204 and the source finger 208.

The drain finger 204 can have a drain finger length 214 extending along a Y axis and a plurality of different drain finger widths 216, 218, 220, 222 along the drain finger length 214 such that current density is equal or substantially equal (within a percentage range of 0.1-5%) at each point along the drain finger length 214. The source finger 208 can have a source finger length 224 extending along the Y axis and a plurality of different source finger widths 226, 228, 230, 232 along the source finger length 224 such that current density is equal at each point along the source finger length 224.

The drain finger 204 can include a first drain finger width 216 at a point along the drain finger length 214 nearest the drain contact 202 and at least one other drain finger width 218, 220 or 222 smaller than the first drain finger width 216. The at least one other drain finger width 218, 220 or 222 can be at a point along the drain finger length 214 further from the drain contact 202 than the first drain finger width 216.

Similarly, the source finger 208 can have a first source finger width 226 at a point along the source finger length 228 nearest the source contact 206 and at least one other source finger width 228, 230, 232 smaller than the first source finger width 226. The other source finger width/s 228, 230, 232 can be at one or more point/s along the source finger length 224 further from the source contact 206 than the first source finger width 226.

While four source finger widths 226, 228, 230, 232 are shown, there may be more or fewer width/s (e.g., tapering can occur with more or fewer steps or widths along the length of the source finger). Similarly, while four drain finger widths 216, 218, 220, 222 are shown, there may be more or fewer width/s (e.g., tapering can occur with more or fewer steps or widths along the length of the drain finger).

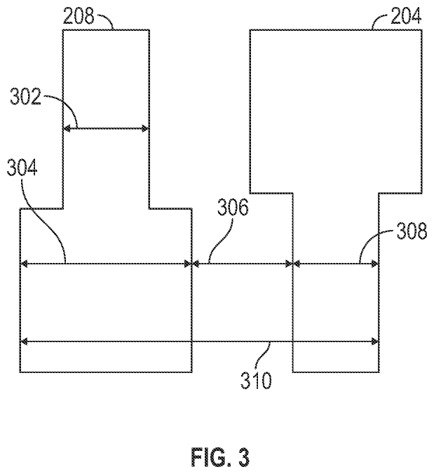

FIG. 3 illustrates example proportions and layout of transistor devices in accordance with some aspects. As seen in FIG. 3, a distance 306 between the drain finger 208 and the source finger 204 can be constant or near-constant along the drain finger length and the source finger length. An overall width 310 of the transistor can also be maintained. In examples, a smallest-width taper of the source finger 208 can have a same width 302 as a smallest-width taper 308 of the drain finger 204. Similarly, in examples, a largest-width taper of the source finger 208 can have a same width 304 as a largest-width taper of the drain finger 204. Proportionate widths can extend along lengths of each of the source finger 208 and drain finger 204 such that a constant distance 306 is maintained between the source finger 208 and the drain finger 204. As the widths can be kept relatively constant relative to previous designs, overall area of a transistor device can be kept the same or near-same while maintaining current density without increasing parasitic contributions of the transistor device 200 (FIG. 2).

Referring again to FIG. 2, the device 200 can include a plurality of layers. Electrical connections (e.g., vias) 234 can be provided between at least two of the plurality of layers and below at least one discrete width segment 226, 228, 230, 232 of the source finger and at least one discrete width segment 216, 218, 220, 232 of the drain finger 204.

Current within the transistor device 200 can flow from the drain contact 202 to the source contact 206 by flowing from drain metal layers to electrical contacts (e.g., through the electrical connections or vias 234). From the electrical contacts 234, current flows through the diffusion area 210 that connects the source contact 206 and drain contact 202 (e.g., in silicon or non-metal portions below the electrical connections 234). From the diffusion area 210, current flows to source electrical connections (or vias) 236 and from there to metal source metal layers 206.

As current propagates through the finger 204, the current amplitude decreases along the way because some of the current is provided from the drain finger 204 to the source finger 208 through the diffusion area 210 (e.g., in the X direction from drain contact 202 to source contact 206). Because the width of the metal decreases along the length of the metal finger 204, current density remains the same given that current density equals current divided by width, i.e., if metal width is decreased by the same factor as current along the FET finger, current density remains the same. A constant or maintained current density improves the KPIs of power amplifiers as described earlier herein and accordingly the transistor design of example aspects improves the KPIs of power amplifiers used in many modern user devices.

In addition, the electrical contacts 234, 236 do not extend along the entire length of drain finger 204 and drain finger 208, and current is reduced at each metal contact 234, 236. Current flows (and decreases) at each electrical contact 234, 236 and accordingly width should be reduced at each electrical contact 234, 236 to maintain the same current density.

Increasing metal width on one side of the finger and decreasing it on the other side (by the same value) does not change the distance between metal fingers, meaning that capacitance between FET fingers does not increase.

It will further be appreciated that example transistor device 200 can be included in other driver stages or other devices in addition to the power amplifiers described herein. Transistors according to aspects are not limited to usage in any particular type of device or apparatus.

### Other Systems and Apparatuses

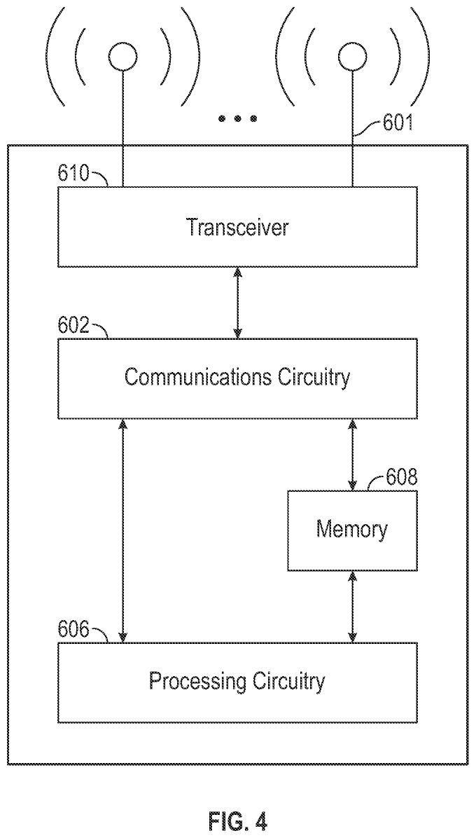

FIG. 4 illustrates a functional block diagram of a wireless communication device, in accordance with some embodiments. In some embodiments, FIG. 4 illustrates a functional block diagram of a communication device (STA) that may be suitable for use as an AP STA, a non-AP STA or other user device in accordance with some embodiments. The communication device may also be suitable for use as a handheld device, a mobile device, a cellular telephone, a smartphone, a tablet, a netbook, a wireless terminal, a laptop computer, a wearable computer device, a femtocell, a high data rate (HDR) subscriber device, an access point, an access terminal, or other personal communication system (PCS) device.

The communication device may include communications circuitry 602 and transceiver circuitry 610 for transmitting and receiving signals to and from other communication devices using one or more antennas 601. The communications circuitry 602 may include circuitry that can operate the physical layer (PHY) communications and/or medium access control (MAC) communications for controlling access to the wireless medium, and/or any other communications layers for transmitting and receiving signals. The communication device may also include processing circuitry 606 and memory 608 arranged to perform the operations described herein. In some embodiments, the communications circuitry 602 and the processing circuitry 606 may be configured to perform operations detailed in the above figures, diagrams, and flows.

In accordance with some embodiments, the communications circuitry 602 may be arranged to contend for a wireless medium and configure frames or packets for communicating over the wireless medium. The communications circuitry 602 may be arranged to transmit and receive signals. The communications circuitry 602 may also include circuitry for modulation/demodulation, upconversion/downconversion, filtering, amplification, etc. In some embodiments, the processing circuitry 606 of the communication device may include one or more processors. In other embodiments, two or more antennas 601 may be coupled to the communications circuitry 602 arranged for sending and receiving signals. The memory 608 may store information for configuring the processing circuitry 606 to perform operations for configuring and transmitting message frames and performing the various operations described herein. The memory 608 may include any type of memory, including non-transitory memory, for storing information in a form readable by a machine (e.g., a computer). For example, the memory 608 may include a computer-readable storage device, read-only memory (ROM), random-access memory (RAM), magnetic disk storage media, optical storage media, flash-memory devices and other storage devices and media.

In some embodiments, the communication device may be part of a portable wireless communication device, such as a personal digital assistant (PDA), a laptop or portable computer with wireless communication capability, a web tablet, a wireless telephone, a smartphone, a wireless headset, a pager, an instant messaging device, a digital camera, an access point, a television, a medical device (e.g., a heart rate monitor, a blood pressure monitor, etc.), a wearable computer device, or another device that may receive and/or transmit information wirelessly.

In some embodiments, the communication device may include one or more antennas 601. The antennas 601 may include one or more directional or omnidirectional antennas, including, for example, dipole antennas, monopole antennas, patch antennas, loop antennas, microstrip antennas, or other types of antennas suitable for transmission of RF signals. In some embodiments, instead of two or more antennas, a single antenna with multiple apertures may be used. In these embodiments, each aperture may be considered a separate antenna. In some multiple-input multiple-output (MIMO) embodiments, the antennas may be effectively separated for spatial diversity and the different channel characteristics that may result between each of the antennas and the antennas of a transmitting device.

In some embodiments, the communication device may include one or more of a keyboard, a display, a non-volatile memory port, multiple antennas, a graphics processor, an application processor, speakers, and other mobile device elements. The display may be an LCD screen including a touch screen.

Although the communication device is illustrated as having several separate functional elements, two or more of the functional elements may be combined and may be implemented by combinations of software-configured elements, such as processing elements including digital signal processors (DSPs), and/or other hardware elements. For example, some elements may include one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements of the communication device may refer to one or more processes operating on one or more processing elements.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

References to “one aspect”, “an aspect”, “an example aspect,” “some aspects,” “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to and are not intended to imply that the objects so described must be in a given sequence, either temporally, spatially, in ranking, or in any other manner.

The term “wireless device”, as used herein, includes, for example, a device capable of wireless communication, a communication device capable of wireless communication, a communication station capable of wireless communication, a portable or non-portable device capable of wireless communication, or the like. In some demonstrative aspects, a wireless device may be or may include a peripheral that is integrated with a computer, or a peripheral that is attached to a computer. In some demonstrative aspects, the term “wireless device” may optionally include a wireless service.

The term “communicating” as used herein with respect to a communication signal includes transmitting the communication signal and/or receiving the communication signal. For example, a communication unit, which is capable of communicating a communication signal, may include a transmitter to transmit the communication signal to at least one other communication unit, and/or a communication receiver to receive the communication signal from at least one other communication unit. The verb communicating may be used to refer to the action of transmitting and/or the action of receiving. In one example, the phrase “communicating a signal” may refer to the action of transmitting the signal by a first device and may not necessarily include the action of receiving the signal by a second device. In another example, the phrase “communicating a signal” may refer to the action of receiving the signal by a first device and may not necessarily include the action of transmitting the signal by a second device.

As used herein, the term “circuitry” may, for example, refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality. In some aspects, circuitry may include logic, at least partially operable in hardware. In some aspects, the circuitry may be implemented as part of and/or in the form of a radio virtual machine (RVM), for example, as part of a Radio processor (RP) configured to execute code to configured one or more operations and/or functionalities of one or more radio components.

The term “antenna” or “antenna array,” as used herein, may include any suitable configuration, structure and/or arrangement of one or more antenna elements, components, units, assemblies and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a single element antenna, a set of switched beam antennas, and/or the like.

### Additional Notes and Aspects

Example 1 is a transistor device including: a drain contact operably connected to a drain finger; a source contact operably connected to a source finger; a diffusion area connected to the drain finger and the source finger to provide current to the drain finger and the source finger; the drain finger having a drain finger length extending along an axis and a plurality of different drain finger widths along the drain finger length such that current density is equal at each point along the drain finger length; and the source finger having a source finger length extending along the axis and a plurality of different source finger widths along the source finger length such that current density is equal at each point along the source finger length.

In Example 2, the subject matter of Example 1 can optionally include wherein the drain finger has a first drain finger width at a point along the drain finger length nearest the drain contact and at least one other drain finger width smaller than the first drain finger width, the at least one other drain finger width being at a point along the drain finger length further from the drain contact than the first drain finger width.

In Example 3, the subject matter of Example 2 can optionally include wherein the source finger has a first source finger width at a point along the source finger length nearest the source contact and at least one other source finger width smaller than the first source finger width, the at least one other source finger width being at a point along the source finger length further from the source contact than the first source finger width.

In Example 4, the subject matter of Example 2 can optionally include wherein the transistor device comprises a plurality of layers.

In Example 5, the subject matter of Example 4 can optionally include electrical connections between at least two of the plurality of layers, the electrical connections provided below at least one discrete width segment of the source finger and at least one discrete width segment of the drain finger.

In Example 6, the subject matter of any of Examples 1-5 can optionally include wherein a distance between the drain finger and the source finger is constant along the drain finger length and the source finger length.
Example 7 is driver stage circuitry comprising: an input terminal and an output terminal; and at least one transistor device coupled between the input terminal and the output terminal, the transistor device comprising: a drain contact electrically connected to a drain finger; a source contact electrically connected to a source finger; a diffusion area between the drain finger and the source finger to provide current between the drain finger and the source finger; the drain finger having a drain finger length extending along a Y axis and a plurality of different drain finger widths along the drain finger length such that current density is equal at each point along the drain finger length; and the source finger having a source finger length extending along the Y axis and a plurality of different source finger widths along the source finger length such that current density is equal at each point along the source finger length.

In Example 8, the subject matter of Example 7 can optionally include wherein the drain finger has a first drain finger width at a point along the drain finger length nearest the drain contact and at least one other drain finger width smaller than the first drain finger width, the at least one other drain finger width being at a point along the drain finger length further from the drain contact than the first drain finger width.

In Example 9, the subject matter of Example 8 can optionally include wherein the source finger has a first source finger width at a point along the source finger length nearest the source contact and at least one other source finger width smaller than the first source finger width, the at least one other source finger width being at a point along the source finger length further from the source contact than the first source finger width.

In Example 10, the subject matter of Example 8 can optionally include wherein the transistor device comprises a plurality of layers.

In Example 11, the subject matter of Example 10 can optionally include wherein the transistor device further comprises electrical connections between at least two of the plurality of layers, the electrical connections provided below at least one discrete width segment of the source finger and at least one discrete width segment of the drain finger.

In Example 12, the subject matter of any of Examples 7-11 can optionally include wherein a distance between the drain finger and the source finger is constant along the drain finger length and the source finger length.
Example 13 is a user device including a front end module including: at least one antenna; at least one driver stage circuitry, the at least driver stage circuitry including: an input terminal and an output terminal; at least one transistor apparatus coupled between the input terminal and the output terminal, the transistor device comprising: a drain contact electrically connected to a drain finger; a source contact electrically connected to a source finger; a diffusion area between the drain finger and the source finger to provide current between the drain finger and the source finger; the drain finger having a drain finger length extending along a Y axis and a plurality of different drain finger widths along the drain finger length such that current density is equal at each point along the drain finger length; and the source finger having a source finger length extending along the Y axis and a plurality of different source finger widths along the source finger length such that current density is equal at each point along the source finger length.

In Example 14, the subject matter of Example 13 can optionally include wherein the drain finger has a first drain finger width at a point along the drain finger length nearest the drain contact and at least one other drain finger width smaller than the first drain finger width, the at least one other drain finger width being at a point along the drain finger length further from the drain contact than the first drain finger width.

In Example 15, the subject matter of Example 14 can optionally include wherein the source finger has a first source finger width at a point along the source finger length nearest the source contact and at least one other source finger width smaller than the first source finger width, the at least one other source finger width being at a point along the source finger length further from the source contact than the first source finger width.

In Example 16, the subject matter of Example 15 can optionally include wherein the transistor device comprises a plurality of layers.

In Example 17, the subject matter of Example 16 can optionally include wherein the transistor device further comprises electrical connections between at least two of the plurality of layers, the electrical connections provided below at least one discrete width segment of the source finger and at least one discrete width segment of the drain finger.

In Example 18, the subject matter of any of Examples 14-17 can optionally include wherein a distance between the drain finger and the source finger is constant along the drain finger length and the source finger length.

In Example 19, the subject matter of any of Examples 14-18 can optionally include two or more antennas.

The above detailed description includes references to the accompanying drawings, which form a part of the detailed description. The drawings show, by way of illustration, specific aspects in which the invention can be practiced. These aspects are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other aspects can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed aspect. Thus, the following claims are hereby incorporated into the Detailed Description, with each claim standing on its own as a separate aspect, and it is contemplated that such aspects can be combined with each other in various combinations or permutations. The scope of the invention should be determined with reference to the appended claims, along with the full scope of equivalents to which such claims are legally entitled.

What is claimed is:

1. A transistor device including:
a drain contact operably connected to a drain finger;
a source contact operably connected to a source finger;
a diffusion area connected to the drain finger and the source finger to provide current to the drain finger and the source finger;
the drain finger having a drain finger length extending along an axis and a plurality of drain finger widths along the drain finger length; and
the source finger having a source finger length extending along the axis and a plurality of source finger widths along the source finger length.

2. The transistor device of claim 1, wherein the drain finger has a first drain finger width at a point along the drain finger length nearest the drain contact and at least one other drain finger width smaller than the first drain finger width, the at least one other drain finger width being at a point along the drain finger length further from the drain contact than the first drain finger width.

3. The transistor device of claim 2, wherein the source finger has a first source finger width at a point along the source finger length nearest the source contact and at least one other source finger width smaller than the first source finger width, the at least one other source finger width being at a point along the source finger length further from the source contact than the first source finger width.

4. The transistor device of claim 2, wherein the transistor device comprises a plurality of layers.

5. The transistor device of claim 4, further comprising electrical connections between at least two of the plurality of layers, the electrical connections provided below at least one discrete width segment of the source finger and at least one discrete width segment of the drain finger.

6. The transistor device of claim 1, wherein a distance between the drain finger and the source finger is constant along the drain finger length and the source finger length.

7. The transistor device of claim 1, wherein the plurality of drain finger widths include different widths such that current density is substantially equivalent at each point along the drain finger length.

8. The transistor device of claim 1, wherein the plurality of source finger widths includes different widths such that current density is substantially equivalent at each point along the source finger length.

9. Driver stage circuitry comprising:
an input terminal and an output terminal; and
at least one transistor device coupled between the input terminal and the output terminal, the transistor device comprising:
a drain contact operably connected to a drain finger;
a source contact operably connected to a source finger;
a diffusion area connected to the drain finger and the source finger to provide current to the drain finger and the source finger;
the drain finger having a drain finger length extending along an axis and a plurality of drain finger widths along the drain finger length; and
the source finger having a source finger length extending along the axis and a plurality of source finger widths along the source finger length.

10. The driver stage circuitry of claim 9, wherein the drain finger widths are configured such that current density is equal at each point along the drain finger length.

11. The driver stage circuitry of claim 9, wherein the source finger widths are such that current density is equal at each point along the source finger length.

12. The driver stage circuitry of claim 9, wherein the drain finger has a first drain finger width at a point along the drain finger length nearest the drain contact and at least one other drain finger width smaller than the first drain finger width, the at least one other drain finger width being at a point along the drain finger length further from the drain contact than the first drain finger width.

13. The driver stage circuitry of claim 12, wherein the source finger has a first source finger width at a point along the source finger length nearest the source contact and at least one other source finger width smaller than the first source finger width, the at least one other source finger width being at a point along the source finger length further from the source contact than the first source finger width.

14. The driver stage circuitry of claim 12, wherein the transistor device comprises a plurality of layers.

15. The driver stage circuitry of claim 14, wherein the transistor device further comprises electrical connections between at least two of the plurality of layers, the electrical connections provided below at least one discrete width segment of the source finger and at least one discrete width segment of the drain finger.

16. The driver stage circuitry of claim 11, wherein a distance between the drain finger and the source finger is constant along the drain finger length and the source finger length.

17. A user device including:
a front end module including:
at least one antenna;
at least one driver stage circuitry, the at least driver stage circuitry including:
an input terminal and an output terminal;
at least one transistor apparatus coupled between the input terminal and the output terminal, the transistor device comprising:
a drain contact operably connected to a drain finger;
a source contact operably connected to a source finger;
a diffusion area connected to the drain finger and the source finger to provide current to the drain finger and the source finger;
the drain finger having a drain finger length extending along an axis and a plurality of drain finger widths along the drain finger length; and
the source finger having a source finger length extending along the axis and a plurality of source finger widths along the source finger length.

18. The user device of claim 17, wherein the plurality of drain finger widths include different widths such that current density is substantially equivalent at each point along the drain finger length, and wherein the plurality of source finger widths includes different widths such that the current density is substantially equivalent at each point along the source finger length.

19. The user device of claim 18, wherein the drain finger has a first drain finger width at a point along the drain finger length nearest the drain contact and at least one other drain finger width smaller than the first drain finger width, the at least one other drain finger width being at a point along the drain finger length further from the drain contact than the first drain finger width, and wherein the source finger has a first source finger width at a point along the source finger length nearest the source contact and at least one other source finger width smaller than the first source finger width, the at least one other source finger width being at a point along the source finger length further from the source contact than the first source finger width.

20. The user device of claim 17, including two or more antennas.
